(19) United States
(12) Patent Application Publication
(10) Pub. No.: US 2026/0250575 A1
(43) Pub. Date: Aug. 27, 2026

(54) METHOD FOR MANUFACTURING SEMICONDUCTOR SUBSTRATE, METHOD FOR ETCHING SUBSTRATE, AND COMPOSITION FOR SURFACE MODIFICATION

(71) Applicant: TOKYO OHKA KOGYO CO., LTD., Kanagawa (JP)

(72) Inventors: Eita SUGA, Kanagawa (JP); Tomoya KUMAGAI, Kanagawa (JP)

(21) Appl. No.: 19/544,346

(22) Filed: Feb. 19, 2026

(30) Foreign Application Priority Data
Feb. 25, 2025 (JP) 2025-027583

(51) Int. Cl. C09K 15/30; H10P 14/60; H10P 50/28; H10W 20/00

(52) U.S. Cl. CPC C09K 15/30; H10P 14/6546; H10P 50/283; H10W 20/055

(57) ABSTRACT

Provided are a method for manufacturing a semiconductor substrate, a method for etching a substrate, and a composition for surface modification, the method for manufacturing a semiconductor substrate including: a step of dry-etching a substrate; and a step of treating the dry-etched substrate with a composition for surface modification, in which the composition for surface modification contains (A) a silane coupling agent represented by General Formula (1) and/or a derivative thereof; and (B) water:

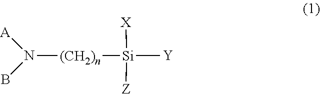

in General Formula (1), A and B each independently represent a hydrogen atom, a hydroxy group, a hydrocarbon group, or an organic group containing a nitrogen atom, and at least one of A and B represents a hydrogen atom; X and Y each independently represent an alkyl group, an alkoxy group, a hydrogen atom, a halogen atom, or a hydroxy group; Z represents an alkoxy group or a hydroxy group; and n represents a number.

### BACKGROUND OF THE INVENTION

### 1. Technical Field

### CROSS-REFERENCE TO RELATED APPLICATION

This application claims priority to Japanese Patent Application No. 2025-027583 filed with the Japan Patent Office on Feb. 25, 2025, the entire contents of which are incorporated herein by reference.

The present invention relates to a method for manufacturing a semiconductor substrate, a method for etching a substrate, and a composition for surface modification.

### 2. Description of the Related Art

In recent years, semiconductor substrates used for integrated circuits and the like have been increasingly miniaturized to achieve higher integration density, such that signal delay in multilayer wiring is suppressed, and securing reliability is required. Accordingly, a Low-k film (Low-k material) having a low dielectric constant is used as an interlayer insulating film of a semiconductor substrate. The Low-k film is patterned by dry etching. Thereafter, in order to prevent diffusion of a wiring material such as Cu into the Low-k film, a step of forming a barrier layer such as TaN is performed as a subsequent step after the dry etching.

As a technology relating to the Low-k film described above, for example, Patent Literature 1 discloses a method for processing a dielectric film, the method including exposing at least one surface of the dielectric film to a processing compound containing an alkylsilane, an alkoxysilane, an alkylsiloxane, an alkoxysiloxane, an arylsilane, an acylsilane, a cyclosiloxane, a polysilsesquioxane (PSS), an arylsiloxane, an acylsiloxane, a halosiloxane, or any combination thereof, in which the dielectric film has a dielectric constant smaller than a dielectric constant of SiO₂.

### PATENT LITERATURE

Patent Literature 1: JP 2008-532268 A

### SUMMARY OF THE INVENTION

However, since the Low-k film is damaged by dry etching, in a barrier layer formation step performed after the dry etching, the Low-k film is further damaged, resulting in a problem in that electrical characteristics of the semiconductor substrate are degraded. Accordingly, in semiconductor substrate manufacturing processes and etching technologies, there is a demand for development of a technology capable of repairing damage to the Low-k film and promoting formation of a barrier layer in a subsequent step.

The present invention has been made in view of the above-described problems, and an object thereof is to provide a method for manufacturing a semiconductor substrate, a method for etching a substrate, and a composition for surface modification, which can contribute to improvement of a dielectric constant of a Low-k film without causing defective formation of a barrier layer.

As a result of intensive studies in order to achieve the above-described object, the present inventors have found that a method for manufacturing a semiconductor substrate, the method including a step of dry-etching a substrate including a layer containing a Low-k material and a step of treating the dry-etched substrate with a composition for surface modification, in which the composition for surface modification contains (A) a silane coupling agent having a specific structure and/or a derivative thereof and (B) water, is effective, thereby completing the present invention.

That is, the present invention is as follows.
<1>
A method for manufacturing a semiconductor substrate, the method including: a step of dry-etching a substrate including a layer containing a Low-k material; and a step of treating the dry-etched substrate with a composition for surface modification, in which the composition for surface modification contains: (A) a silane coupling agent represented by General Formula (1) and/or a derivative thereof; and (B) water,

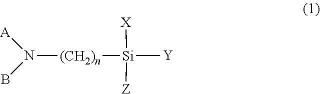

wherein, in General Formula (1), A and B each independently represent a hydrogen atom, a hydroxy group, a hydrocarbon group, or an organic group containing a nitrogen atom, and at least one of A and B represents a hydrogen atom; X and Y each independently represent an alkyl group, an alkoxy group, a hydrogen atom, a halogen atom, or a hydroxy group; Z represents an alkoxy group or a hydroxy group; and n represents a number.
<2>
The method for manufacturing a semiconductor substrate according to <1>, in which the composition for surface modification further contains (C) a corrosion inhibitor.
<3>
The method for manufacturing a semiconductor substrate according to <2>, in which the corrosion inhibitor (C) is a compound having an aromatic ring structure containing a nitrogen atom.
<4>
The method for manufacturing a semiconductor substrate according to any one of <1> to <3>, in which a content of the component (A) in the composition for surface modification is from 0.01 to 10 mass %.
<5>
The method for manufacturing a semiconductor substrate according to <2> or <3>, in which a content of the component (C) in the composition for surface modification is from 0.001 to 5 mass %.
<6>
The method for manufacturing a semiconductor substrate according to any one of <1> to <5>, in which the composition for surface modification has a pH of 6.0 to 12.0.
<7>
A method for etching a substrate, the method including: a step of dry-etching a substrate including a layer containing a Low-k material; and a step of treating the dry-etched substrate with a composition for surface modification, in which the composition for surface modification contains: (A) a silane coupling agent represented by General Formula (1) and/or a derivative thereof; and (B) water,

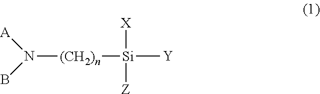

wherein, in General Formula (1), A and B each independently represent a hydrogen atom, a hydroxy group, a hydrocarbon group, or an organic group containing a nitrogen atom, and at least one of A and B represents a hydrogen atom; X and Y each independently represent an alkyl group, an alkoxy group, a hydrogen atom, a halogen atom, or a hydroxy group; Z represents an alkoxy group or a hydroxy group; and n represents a number.
<8> The method for etching a substrate according to <7>, in which the composition for surface modification further contains (C) a corrosion inhibitor.
<9>
The method for etching a substrate according to <7> or <8>, in which the composition for surface modification has a pH of 6.0 to 12.0.
<10>
A composition for surface modification of a substrate including a layer containing a Low-k material, the composition containing: (A) a silane coupling agent represented by General Formula (1) and/or a derivative thereof; and (B) water,

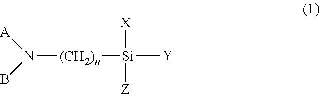

wherein, in General Formula (1), A and B each independently represent a hydrogen atom, a hydroxy group, a hydrocarbon group, or an organic group containing a nitrogen atom, and at least one of A and B represents a hydrogen atom; X and Y each independently represent an alkyl group, an alkoxy group, a hydrogen atom, a halogen atom, or a hydroxy group; Z represents an alkoxy group or a hydroxy group; and n represents a number.
<11>
The composition for surface modification according to <10>, further containing (C) a corrosion inhibitor.
<12>
The composition for surface modification according to <11>, in which the corrosion inhibitor (C) is a compound having an aromatic ring structure containing a nitrogen atom.
<13>
The composition for surface modification according to any one of <10> to <12>, in which a content of the component (A) in the composition for surface modification is from 0.01 to 10 mass %.
<14>
The composition for surface modification according to <11> or <12>, in which a content of the component (C) in the composition for surface modification is from 0.001 to 5 mass %.
<15>
The composition for surface modification according to any one of <10> to <14>, in which the composition for surface modification has a pH of 6.0 to 12.0.

According to the present invention, it is possible to provide a method for manufacturing a semiconductor substrate, a method for etching a substrate, and a composition for surface modification, which can repair damage to a Low-k film while promoting formation of a barrier layer in a subsequent step.

### DETAILED DESCRIPTION

Hereinafter, an embodiment for carrying out the present invention (hereinafter, simply referred to as “the present embodiment”) will be described in detail. The following present embodiment is an example for describing the present invention, and is not intended to limit the present invention to the following contents. The present invention can be appropriately modified and implemented within the scope of the gist thereof. In addition, the configurations and parameters disclosed in the present specification can be any combination unless otherwise specified. Furthermore, an upper limit and a lower limit of the values disclosed in the present specification can be any combination unless otherwise specified.

In addition, in the present specification, the term “comprise” or “contain” may be replaced with “be”, “consist essentially of” and “consist of” as necessary. Further, the expression “A and/or B” means “A, B, or both”, unless otherwise specified.

Note that, in the present specification, the expression “doing something or to do something” may refer to “process” or “step”, “process” may refer to “doing something or to do something” or “step”, and “step” may refer to “doing something or to do something” or “process”. In addition, in the present specification, the term “process” such as “step” may refer to “apparatus or unit that is configured to perform the step”, the term “apparatus” may refer to “mechanism or unit”, and the term “unit” may refer to “unit or apparatus provided for a mechanism, an apparatus, or a system”.

### <Method for Manufacturing Semiconductor Substrate>

A method for manufacturing a semiconductor substrate of the present embodiment includes a step of dry-etching a substrate including a layer containing a Low-k material; and a step of treating the dry-etched substrate with a composition for surface modification, in which the composition for surface modification contains (A) a silane coupling agent represented by General Formula (1) and/or a derivative thereof; and (B) water. Hereinafter, a substrate including a layer containing a Low-k material may be referred to as a “laminated substrate”.

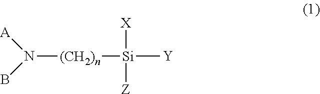

In the formula, A and B each independently represent a hydrogen atom, a hydroxy group, a hydrocarbon group, or an organic group containing a nitrogen atom, and at least one of A and B represents a hydrogen atom; X and Y each independently represent an alkyl group, an alkoxy group, a hydrogen atom, a halogen atom, or a hydroxy group; Z represents an alkoxy group or a hydroxy group; and n represents a number.

The present inventors have focused on problems of conventional methods for manufacturing semiconductor substrates, including a problem in which electrical characteristics are degraded due to damage to a Low-k film when the Low-k film is dry-etched, and a problem in which formability of a barrier layer is poor in a barrier layer formation step, which is a subsequent step after the dry etching. The present inventors have considered that one of the causes of the above-described problems may be that a surface of a Low-k material is altered by an etching gas used in dry etching, thereby changing polarity of the surface. As one example, during dry etching, hydroxyl groups (—OH) derived from water (H₂O) may be introduced onto the surface of the Low-k film, thereby increasing polarity.

Based on the above considerations, as a result of intensive studies, the present inventors have unexpectedly found that the above-described problems can be solved by treating a substrate after dry etching with the above-described composition for surface modification. Although the reason therefor is not clear, it is considered that the silane coupling agent (A) and/or a derivative thereof contained in the composition for surface modification can repair the surface of the Low-k film whose polarity has been changed, and that a nitrogen atom in the silane coupling agent (A) and/or a derivative thereof acts as a reaction site for barrier layer formation, thereby promoting formation of a barrier layer in a subsequent step (however, the mechanism and effects of the present embodiment are not limited thereto).

Furthermore, when metal wiring and the like of a semiconductor substrate are miniaturized, an exposed surface area of the metal wiring and the like naturally increases with the miniaturization, and thus a contact area with an etching gas used in dry etching also increases. For this reason, a surface area of a Low-k film that is damaged tends to increase, and an area in which formability of a barrier layer is poor tends to increase. Accordingly, a semiconductor substrate having miniaturized metal wiring exhibits a remarkable decrease in electrical characteristics due to dry etching. However, according to the method for manufacturing a semiconductor substrate of the present embodiment, damage to a Low-k film can be repaired while promoting formation of a barrier layer in a subsequent step, and thus demands for miniaturization of semiconductor substrates can also be satisfied (however, the mechanism and effects of the present embodiment are not limited thereto).

Hereinafter, the respective steps of the method for manufacturing a semiconductor substrate according to the present embodiment and a composition and the like of the composition for surface modification will be described in more detail.

### (Dry Etching Step)

In the dry etching step, a substrate including a layer containing a Low-k material is dry-etched. Specific examples of the substrate including a layer containing a Low-k material may include a laminated substrate in which a metal wiring layer, an etching stop layer (etch stopper), and a Low-k film containing a Low-k material (interlayer insulating film) are laminated on a substrate, and a hard mask layer (HM layer) is further provided thereon (substrate/metal wiring layer/etching stop layer/Low-k film (interlayer insulating film)/HM layer). In the method for manufacturing a semiconductor substrate according to the present embodiment, various functional layers other than the layers described above may be further laminated, as long as desired effects can be obtained, and it goes without saying that the layer structure is not limited. For example, the above-described layers laminated on the substrate are not particularly limited in terms of their kinds, sizes, shapes, numbers of layers, and lamination order, and a desired configuration can be adopted.

The substrate is not particularly limited, and examples thereof may include a substrate containing at least one selected from the group consisting of silicon, amorphous silicon, and glass.

Examples of the metal wiring layer may include, but are not particularly limited to, a metal wiring layer containing at least one selected from the group consisting of metals such as molybdenum (Mo), tungsten (W), ruthenium (Ru), copper (Cu), gold (Au), silver (Ag), iron (Fe), nickel (Ni), aluminum (Al), lead (Pb), zinc (Zn), tin (Sn), tantalum (Ta), magnesium (Mg), cobalt (Co), bismuth (Bi), cadmium (Cd), titanium (Ti), zirconium (Zr), antimony (Sb), manganese (Mn), beryllium (Be), chromium (Cr), germanium (Ge), vanadium (V), gallium (Ga), hafnium (Hf), indium (In), niobium (Nb), rhenium (Re), and thallium (Tl), and metal oxides, metal nitrides, metal chlorides, and metal fluorides thereof.

The etching stop layer is not particularly limited, and examples thereof may include an etching stop layer containing at least one selected from the group consisting of silicon-based materials such as SiN, SiON, and SiOCN, metal nitrides such as AlN, and metal oxides such as AlOₓ.

The Low-k film (interlayer insulating film) containing a Low-k material is not particularly limited, and examples thereof may include SiOC, SiCOH, and SiOCN. In general, a material having a dielectric constant lower than that of SiO₂ (dielectric constant k=4.1) or the like is suitably used. The Low-k film is patterned by dry etching so that unnecessary portions are removed to obtain a predetermined pattern shape. However, a surface exposed after the removal is damaged by the dry etching. As the area of the exposed surface increases, an influence of damage caused by the dry etching increases.

The hard mask layer (HM layer) may be a layer containing a material that functions as a protective film against dry etching, and the material thereof is not particularly limited; a suitable material may be appropriately selected in consideration of manufacturing conditions and the like. By providing a patterned HM layer, the Low-k film and the like can be dry-etched so as to correspond to the pattern. Examples of the HM layer may include a hard mask layer containing at least one selected from the group consisting of TiOₓ, TiN, ZrOₓ, WDC (tungsten-doped carbon), CHM (carbon hard mask), and SiHM (silicon hard mask, such as SiN and SiO₂).

A method for forming the above-described various layers on the substrate is not particularly limited, and examples thereof may include an atomic layer deposition method (ALD method), a sputtering method, a chemical vapor deposition method (CVD method), a physical vapor deposition method (PVD method), and a spin-on method. A film formed by these methods and the like may be subjected to plasma treatment.

The substrate including a layer containing a Low-k material preferably includes a Low-k film (interlayer insulating film) containing a Low-k material and a functional layer containing at least one selected from the group consisting of copper atoms, cobalt atoms, tungsten atoms, and molybdenum atoms. The functional layer is not particularly limited, and examples thereof may include the metal wiring layer described above. The substrate may further include an etching stop layer as needed, and may further include a hard mask layer (HM layer) on the outermost surface thereof.

The method and conditions of dry etching are not particularly limited, and suitable methods and conditions may be adopted in consideration of materials, configurations, and the like of a laminated substrate to be processed. Examples thereof may include plasma etching, sputter etching, and reactive ion etching. Examples thereof may include a method of etching using an inorganic fluorine gas such as CₓH_{y}F_{z} (where x, y, and z each independently represent a number), F₂, or SF₆, or an organic fluorine gas. As an etching apparatus, an etching apparatus such as a capacitively coupled plasma (CCP) apparatus or an inductively coupled plasma (ICP) apparatus may be employed.

While dry etching has a characteristic of excellent anisotropy, it has a problem in that a substrate to be etched is susceptible to damage, and in particular, a surface of a Low-k film is susceptible to damage. However, according to the manufacturing method of the present embodiment, by treating the substrate in a treatment step described below using a composition for surface modification containing (A) a silane coupling agent represented by General Formula (1) and/or a derivative thereof and (B) water, damage to the Low-k film can be repaired while promoting formation of a barrier layer in a subsequent step.

### (Treatment Step and Composition for Surface Modification)

In a step of treating a dry-etched substrate with a composition for surface modification (treatment step), a composition for surface modification containing (A) a silane coupling agent having a structure represented by General Formula (1) and/or a derivative thereof and (B) water is used. By using such a composition for surface modification, damage to a Low-k film can be repaired while promoting formation of a barrier layer in a subsequent step.

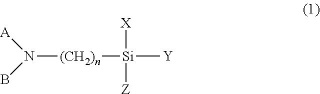

In the formula, A and B each independently represent a hydrogen atom, a hydroxy group, a hydrocarbon group, or an organic group containing a nitrogen atom, and at least one of A and B represents a hydrogen atom; X and Y each independently represent an alkyl group, an alkoxy group, a hydrogen atom, a halogen atom, or a hydroxy group; Z represents an alkoxy group or a hydroxy group; and n represents a number.

((A) Component: Silane Coupling Agent and/or Derivative Thereof)

In General Formula (1), A and B each independently represent a hydrogen atom, a hydroxy group, a hydrocarbon group, or an organic group containing a nitrogen atom, and at least one of A and B represents a hydrogen atom.

The hydrocarbon group is preferably an alkyl group having 1 to 8 carbon atoms. The lower limit of the number of carbon atoms is more preferably 2 or more, and even more preferably 3 or more. The upper limit of the number of carbon atoms is more preferably 7 or less, and even more preferably 6 or less.

The organic group containing a nitrogen atom is preferably a monovalent organic group containing only nitrogen atoms, carbon atoms, and hydrogen atoms; more preferably at least one selected from the group consisting of —(CH₂)ₚ—NH₂ (where p represents a number of 1 to 5) and —(CH₂)_{q}—NH(CH₂)—(CH₂)ₛ—NH₂ (where q, r, and s each independently represent a number of 1 to 5); and even more preferably at least one selected from the group consisting of —(CH₂)ₜ—NH₂ (where t represents a number of 1 to 3) and —(CH₂)ᵤ—NH(CH₂)ᵥ—(CH₂)_{w}—NH₂ (where u, v, and w each independently represent a number of 1 to 3).

In General Formula (1), X and Y each independently represent an alkyl group, an alkoxy group, a hydrogen atom, a halogen atom, or a hydroxy group. The alkyl group is preferably an alkyl group having 1 to 5 carbon atoms, more preferably an alkyl group having 1 to 3 carbon atoms, and even more preferably an alkyl group having 1 or 2 carbon atoms. The alkoxy group is preferably at least one selected from the group consisting of a methoxy group, an ethoxy group, an n-propoxy group, and an isopropoxy group.

In General Formula (1), Z represents an alkoxy group or a hydroxy group. The alkoxy group is preferably at least one selected from the group consisting of a methoxy group, an ethoxy group, an n-propoxy group, and an isopropoxy group.

In General Formula (1), n represents a number. n is preferably from 1 to 5, more preferably from 1 to 4, and even more preferably from 1 to 3.

Derivatives of the silane coupling agent represented by General Formula (1) are not particularly limited, as long as the derivatives have structures that can be taken by the silane coupling agent. Examples thereof may include derivatives in which a part or all of the alkoxy groups are hydrolyzed to have silanol groups, and dehydration condensation products of the generated silanols with each other (for example, oligomers and dimers).

Specific examples of the silane coupling agent represented by General Formula (1) may include at least one selected from the group consisting of 3-aminopropyltriethoxysilane (APTES), 3-aminopropyltrimethoxysilane (APTMS), 4-aminobutyltriethoxysilane, 3-(2-aminoethylamino) propyldimethoxymethylsilane (AEAPDMMS), 3-(2-aminoethylamino) propyldiethoxymethylsilane, 3-(2-aminoethylamino) propyltrimethoxysilane, 3-(2-aminoethylamino) propyltriethoxysilane, 4-aminobutyltrimethoxysilane, and 3-[2-(2-aminoethylamino)ethylamino]propyltrimethoxysilane (AEAEAPTMS).

Specific examples of derivatives of the silane coupling agent represented by General Formula (1) may include at least one selected from the group consisting of 3-aminopropylsilanol, 4-aminobutylsilanol, N-(2-aminoethyl)-3-aminopropylsilanol, 3-(2-aminoethylamino) propylmethylsilanol, and 3-[2-(2-aminoethylamino)ethylamino]propylsilanol.

The content of the component (A) in the composition for surface modification is not particularly limited, but is preferably from 0.01 to 10 mass %. The lower limit of the content is more preferably 0.05 mass % or more, even more preferably 0.1 mass % or more, and still even more preferably 0.5 mass % or more. The upper limit of the content is more preferably 8 mass % or less, even more preferably 6 mass % or less, and still even more preferably 5 mass % or less. By controlling the content within such a range, it is possible to further improve effects of modifying a damaged Low-k film while suppressing inhibition of barrier layer formation.

### ((B) Component: Water)

The water is not particularly limited, and from the viewpoint of being suitable for manufacturing a semiconductor substrate, for example, deionized water (DIW) can be used.

The content of the component (B) in the composition for surface modification is not particularly limited, but is preferably from 45 to 99.99 mass %. In addition, the lower limit of the content of water may be, for example, 60 mass % or more, 70 mass % or more, 80 mass % or more, or 85 mass % or more. When the content of water is high, the composition can be suitably used as a so-called water-based composition for surface modification; however, the content of water may also be selected according to the intended use in consideration of, for example, the kind of metal to be cleaned. Note that, during preparation, components required other than water may be added, and water may be added as a balance.

### ((C) Component: Corrosion Inhibitor)

The composition for surface modification preferably further contains (C) a corrosion inhibitor. The corrosion inhibitor is more preferably a compound having an aromatic ring structure containing a nitrogen atom.

Specific examples of the corrosion inhibitor may include, but are not particularly limited to, at least one selected from the group consisting of an imidazole ring-containing compound, a triazole ring-containing compound, a carbazole ring-containing compound, a pyridine ring-containing compound, a pyrimidine ring-containing compound, a tetrazole ring-containing compound, a pyrazole ring-containing compound, a purine ring-containing compound, a phenanthroline ring-containing compound, and a benzothiazole ring-containing compound. Among these, a triazole ring-containing compound and a tetrazole ring-containing compound are more preferable. By using these compounds, it is possible to improve corrosion resistance of various layers containing, for example, copper atoms, cobalt atoms, tungsten atoms, and/or molybdenum atoms (for example, metal wiring layers, etching stop layers, interlayer insulating films, and hard mask layers).

Specific examples of the imidazole ring-containing compound may include 1-decyl-3-methylimidazolium chloride, 2-ethyl-4-methylimidazole, 2-methylimidazole, 2-ethylimidazole, 2-isopropylimidazole, 2-propylimidazole, 2-butylimidazole, 4-methylimidazole, 2,4-dimethylimidazole, 2-undecylimidazole, 2-aminoimidazole, 2,2′-biimidazole, and 5-methylbenzimidazole.

Specific examples of the triazole ring-containing compound may include 1,2,4-triazole (TAZ), 1,2,3-benzotriazole (BTA), 1,2,3-triazole, 3-amino-1H-1,2,4-triazole (3A-TAZ), 1-methyl-1H-benzotriazole, 5-methyl-1H-benzotriazole (5M-BTA), 1-hydroxybenzotriazole, 1-hydroxypropylbenzotriazole, 2,3-dicarboxypropylbenzotriazole, 4-hydroxybenzotriazole, 4-carboxyl-1H-benzotriazole, 4-carboxyl-1H-benzotriazole methyl ester, 4-carboxyl-1H-benzotriazole butyl ester, 4-carboxyl-1H-benzotriazole octyl ester, 5-hexylbenzotriazole, [1,2,3-benzotriazolyl-1-methyl][1,2,4-triazolyl-1-methyl][2-ethylhexyl]amine, tolyltriazole, naphthotriazole, bis[(1-benzotriazolyl)methyl]phosphonic acid, and 3-aminotriazole. Among these, 1,2,4-triazole (TAZ), 1,2,3-benzotriazole (BTA), 1,2,3-triazole, 3-amino-1H-1,2,4-triazole (3A-TAZ), 1-methyl-1H-benzotriazole, and 5-methyl-1H-benzotriazole (5M-BTA) are preferable, and 1,2,4-triazole (TAZ), 3-amino-1H-1,2,4-triazole (3A-TAZ), and 5-methyl-1H-benzotriazole (5M-BTA) are more preferable.

Specific examples of the carbazole ring-containing compound may include 9H-carbazole, 4-hydroxycarbazole, 1-methylcarbazole, 3-methyl-9H-carbazole, 9-methyl-1H-carbazole, 2-methoxycarbazole, 1-bromocarbazole, 2-bromocarbazole, 3-bromocarbazole, 4-bromocarbazole, 2-chlorocarbazole, 3-chlorocarbazole, 2-fluorocarbazole, 3-fluorocarbazole, 2-iodocarbazole, 3-iodocarbazole, 9-acetylcarbazole, 2,7-dibromocarbazole, 3,6-dibromocarbazole, 3,6-dichlorocarbazole, 2,3-benzocarbazole, 9-acetyl-3,6-diiodocarbazole, 2-bromo-7-methoxy-9H-carbazole, 3,6-dimethylcarbazole, 2,7-dimethylcarbazole, 3,6-diaminocarbazole, 3-aminoethylcarbazole, 3,6-dimethoxy-9H-carbazole, 2,7-dimethoxy-9H-carbazole, 3,3′-bicarbazole, and 7H-benzo[c]carbazole.

Specific examples of the pyridine ring-containing compound may include 1H-1,2,3-triazolo[4,5-b]pyridine, 1,2,4-triazolo[4,3-a]pyridin-3 (2H)-one, 3H-1,2,3-triazolo[4,5-b]pyridin-3-ol, 1-acetyl-1H-1,2,3-triazolo[4,5-b]pyridine, 3-aminopyridine, 4-aminopyridine, 3-hydroxypyridine, 4-hydroxypyridine, 2-acetamidopyridine, 4-pyrrolidinopyridine, 2-cyanopyridine, 2,2′-bipyridyl, 4,4′-dimethyl-2,2′-bipyridyl, 4,4′-di-tert-butyl-2,2′-bipyridyl, and 4,4′-dinonyl-2,2′-bipyridyl.

Specific examples of the pyrimidine ring-containing compound may include pyrimidine, 1,2,4-triazolo[1,5-a]pyrimidine, 1,3,4,6,7,8-hexahydro-2H-pyrimido[1,2-a]pyrimidine, 1,3-diphenyl-pyrimidine-2,4,6-trione, 1,4,5,6-tetrahydropyrimidine, 2,4,5,6-tetraaminopyrimidine sulfate, 2,4,5-trihydroxypyrimidine, 2,4,6-triaminopyrimidine, 2,4,6-trichloropyrimidine, 2,4,6-trimethoxypyrimidine, 2,4,6-triphenylpyrimidine, 2,4-diamino-6-hydroxylpyrimidine, 2,4-diaminopyrimidine, 2-acetamidopyrimidine, 2-aminopyrimidine, 2-methyl-5,7-diphenyl-(1,2,4)triazolo (1,5-a)pyrimidine, 2-methylsulfanyl-5,7-diphenyl-(1,2,4)triazolo (1,5-a)pyrimidine, 2-methylsulfanyl-5,7-diphenyl-4,7-dihydro-(1,2,4)triazolo (1,5-a)pyrimidine, and 4-aminopyrazolo[3,4-d]pyrimidine.

Examples of the tetrazole ring-containing compound may include 2,3,5-triphenyltetrazole, 2,3,5-triphenyltetrazolium chloride, 2,3,5-triphenyltetrazolium bromide, 1H-tetrazole, 5-amino-1H-tetrazole, 5-methyl-1H-tetrazole, 5-phenyl-1H-tetrazole, and 1-(2-diaminoethyl)-5-mercaptotetrazole.

Examples of the pyrazole ring-containing compound may include 3,5-dimethylpyrazole, 3-amino-5-methylpyrazole, 4-methylpyrazole, 3-amino-5-hydroxypyrazole, 3-phenylpyrazole, indazole, 4-fluoroindazole, 5-nitroindazole, indazole-3-carboxylic acid, and benzydamine hydrochloride. Among these, 3-phenylpyrazole, indazole, 4-fluoroindazole, 5-nitroindazole, indazole-3-carboxylic acid, and benzydamine hydrochloride are preferable.

Specific examples of the purine ring-containing compound may include purines.

Specific examples of the phenanthroline ring-containing compound may include 1,10-phenanthroline.

Specific examples of the benzothiazole ring-containing compound may include benzothiazole, 2,5-dimethylbenzothiazole, and 2,6-dimethylbenzothiazole.

The corrosion inhibitor may also be a salt of the compounds described above. Specific examples of the salt may include, but are not particularly limited to, a sodium salt, a potassium salt, a chloride salt, an ammonium salt, and an alkylammonium salt (for example, a tetramethylammonium salt). The corrosion inhibitor may also be a hydrate of the compounds described above.

The corrosion inhibitor may be used alone or in combination of two or more. From the viewpoint that corrosion inhibition effects can be imparted to various kinds of metals, the composition for surface modification may contain two or more kinds of corrosion inhibitors. The corrosion inhibitor can be selected according to the kind of each target layer (for example, a metal wiring layer, an etching stop layer, an interlayer insulating film, and a hard mask layer). When the composition for surface modification contains two or more corrosion inhibitors, it more preferably contains at least two selected from the group consisting of an imidazole ring-containing compound, a triazole ring-containing compound, a carbazole ring-containing compound, a pyridine ring-containing compound, a pyrimidine ring-containing compound, a tetrazole ring-containing compound, a pyrazole ring-containing compound, a purine ring-containing compound, and a phenanthroline ring-containing compound. Any of the compounds described above may be used as these compounds.

The content of the component (C) in the composition for surface modification is preferably from 0.001 to 5 mass %. The lower limit of the content is more preferably 0.03 mass % or more, even more preferably 0.05 mass % or more, and still even more preferably 0.1 mass % or more. The upper limit of the content is more preferably 3 mass % or less, even more preferably 2 mass % or less, and still even more preferably 1 mass % or less. When two or more corrosion inhibitors are contained as the component (C), a total content thereof is preferably within the above-described range. When the hydrates described above are used as the corrosion inhibitor, a net content excluding water of hydration contained in the hydrate is preferably within the above-described range. By controlling the content of the component (C) within such a range, it is possible to reduce residue on a substrate surface after chemical solution treatment while exhibiting more excellent corrosion resistance.

### (Other Components)

The composition for surface modification may further contain other components, as needed, in addition to the components described above. Examples of the other components may include pH adjusting agents such as organic acids and amines. Specific examples of the organic acids are preferably acetic acid, citric acid, phosphoric acid, sulfuric acid, and methanesulfonic acid. More preferred specific examples of the amines may include tetramethylammonium hydroxide (TMAH), tetraethylammonium hydroxide (TEAH), ammonia (NH₃), ethylenediamine, diethylenetriamine, triethanolamine, and monoethanolamine (MEA).

### (Organic Solvent)

The composition for surface modification may contain an organic solvent. Specific examples of the organic solvent are not particularly limited, and at least one selected from the group consisting of an alcohol-based solvent, a glycol ester-based solvent, a sulfoxide-based solvent, a sulfone-based solvent, an amide-based solvent, a lactone-based solvent, an imidazolidinone-based solvent, a nitrile-based solvent, a ketone-based solvent, an ether-based solvent, an ester-based solvent, a pyrrolidone-based solvent, and a urea-based solvent is preferable. Furthermore, it is more preferable that the composition for surface modification contains, as an organic solvent, only at least one selected from the group consisting of an alcohol-based solvent, a glycol ester-based solvent, a sulfoxide-based solvent, a sulfone-based solvent, an amide-based solvent, a lactone-based solvent, an imidazolidinone-based solvent, a nitrile-based solvent, a ketone-based solvent, an ether-based solvent, an ester-based solvent, a pyrrolidone-based solvent, and a urea-based solvent, and does not contain any other organic solvent.

Specific examples of the alcohol-based solvent may include aliphatic alcohols such as methanol, ethanol, denatured ethanol, isopropanol, n-propanol, n-butanol, and 3-methoxy-3-methyl-1-butanol; and glycols such as ethylene glycol, diethylene glycol, propylene glycol, dipropylene glycol, glycerin, 1,3-propanediol, 1,3-butanediol, 1,4-butanediol, furfuryl alcohol, and hexylene glycol.

Specific examples of the glycol ester-based solvent may include ethylene-based glycol ethers such as ethylene glycol monomethyl ether, ethylene glycol dimethyl ether, diethylene glycol monomethyl ether, diethylene glycol dimethyl ether, triethylene glycol monomethyl ether, triethylene glycol dimethyl ether, ethylene glycol monoethyl ether, ethylene glycol diethyl ether, ethylene glycol monobutyl ether, ethylene glycol dibutyl ether, diethylene glycol monoethyl ether (EDG), diethylene glycol diethyl ether, diethylene glycol monobutyl ether, diethylene glycol dibutyl ether, triethylene glycol monobutyl ether, triethylene glycol dibutyl ether, ethylene glycol monohexyl ether, ethylene glycol dihexyl ether, diethylene glycol monohexyl ether, diethylene glycol dihexyl ether, and ethylene glycol phenyl ether; ethylene-based glycol ether acetates such as ethylene glycol monobutyl ether acetate and diethylene glycol monobutyl ether acetate; propylene-based glycol ethers such as propylene glycol monomethyl ether (PGME), propylene glycol dimethyl ether, dipropylene glycol monomethyl ether (DPM), dipropylene glycol dimethyl ether, tripropylene glycol monomethyl ether, tripropylene glycol dimethyl ether, propylene glycol monoethyl ether, propylene glycol diethyl ether, dipropylene glycol monoethyl ether, dipropylene glycol diethyl ether, tripropylene glycol monoethyl ether, tripropylene glycol diethyl ether, propylene glycol monopropyl ether, propylene glycol dipropyl ether, dipropylene glycol monopropyl ether, dipropylene glycol dipropyl ether, propylene glycol monobutyl ether, propylene glycol dibutyl ether, dipropylene glycol monobutyl ether, dipropylene glycol dibutyl ether, tripropylene glycol monobutyl ether, tripropylene glycol dibutyl ether, and propylene glycol phenyl ether; and propylene-based glycol ether acetates such as propylene glycol methyl ether acetate (PGMEA), dipropylene glycol methyl ether acetate, and propylene glycol diacetate.

Specific examples of the sulfoxide-based solvent may include dimethyl sulfoxide (DMSO), diethyl sulfoxide, dipropyl sulfoxide, diphenyl sulfoxide, and thiophene.

Specific examples of the sulfone-based solvent may include dimethyl sulfone, diethyl sulfone, tetramethylene sulfone, dipropyl sulfone, sulfolane (also known as tetramethylene sulfone), 3-methylsulfolane, 2,4-dimethylsulfolane, 3,4-dimethylsulfolane, diphenylsulfolane, 3,4-diphenylmethylsulfolane, sulfolene, 3-methylsulfolene, and 3-ethylsulfolene.

Specific examples of the amide-based solvent may include dimethylformamide (DMF), diethylformamide (DEF), dimethylacetamide (DMAc), N-methylpyrrolidine (MPD), and hexamethylphosphoramide (HMPA).

Specific examples of the lactone-based solvent may include γ-butyrolactone, α-methyl-γ-butyrolactone, β-propiolactone, γ-valerolactone, δ-valerolactone, γ-caprolactone, ε-caprolactone, γ-laurolactone, and hexanolactone.

Specific examples of the imidazolidinone-based solvent may include 2-imidazolidinone, 1,3-dimethyl-2-imidazolidinone, 1,3-diethyl-2-imidazolidinone, 1,3-dipropyl-2-imidazolidinone, and 1,3-diisopropyl-2-imidazolidinone.

Specific examples of the nitrile-based solvent may include acetonitrile, propionitrile, valeronitrile, and butyronitrile.

Specific examples of the ketone-based solvent may include acetone, methyl ethyl ketone (MEK), methyl isobutyl ketone (MIBK), diisobutyl ketone, cyclohexanone, diacetone alcohol, 1-hexanone, 2-hexanone, 4-heptanone, 2-heptanone (methyl amyl ketone), 1-octanone, 2-octanone, 1-nonanone, 2-nonanone, acetylacetone, acetonylacetone, phenylacetone, acetophenone, methylnaphthyl ketone, methylcyclohexanone, ionone, isophorone, propylene carbonate, diacetonyl alcohol, and acetylcarbinol.

Specific examples of the ether-based solvent may include diisopropyl ether, 1,4-dioxane, methyl tert-butyl ether (MTBE), dimethyl ether, diethyl ether, dipropyl ether, and methyl phenyl ether.

Specific examples of the ester-based solvent may include methyl acetate, ethyl acetate, butyl acetate, amyl acetate, propyl acetate, isopropyl acetate, ethyl methoxyacetate, ethyl ethoxyacetate, acetic acid 2-methoxybutyl(2-methoxybutyl acetate), acetic acid 3-methoxybutyl (3-methoxybutyl acetate), acetic acid 4-methoxybutyl (4-methoxybutyl acetate), acetic acid 3-methoxy-3-methylbutyl (3-methoxy-3-methylbutyl acetate), acetic acid 3-ethyl-3-methoxybutyl (3-ethyl-3-methoxybutyl acetate), 4-methyl-4-methoxypentyl acetate, methyl formate, ethyl formate, propyl formate, butyl formate, methyl lactate, ethyl lactate, propyl lactate, butyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl 3-methoxypropionate, ethyl 3-methoxypropionate, ethyl 3-ethoxypropionate, and propyl 3-methoxypropionate.

Specific examples of the pyrrolidone-based solvent may include N-methylpyrrolidone (NMP), 2-pyrrolidone, and N-vinyl-2-pyrrolidone.

Specific examples of the urea-based solvent may include 1,3-dimethylurea, 1,3-diethylurea, 1,3-dipropylurea, 1,3-diisopropylurea, tetramethylurea, tetraethylurea, tetrapropylurea, tetraisopropylurea, and N,N-dimethylpropyleneurea.

Among the above, the organic solvent as an optional component is preferably a water-soluble organic solvent. Among the above specific examples, as preferred examples of the water-soluble organic solvent, at least one selected from the group consisting of an alcohol-based solvent and a glycol ester-based solvent is preferable; and at least one selected from the group consisting of 1,3-propanediol, glycerin, ethylene glycol, propylene glycol, hexylene glycol, diethylene glycol monoethyl ether (EDG), diethylene glycol monobutyl ether, and dipropylene glycol monomethyl ether (DPM) is more preferable.

The organic solvent is a component that may be optionally added, and when added, the organic solvent may be used alone or two or more kinds may be used in combination.

The composition for surface modification is expected to provide desired effects without using a halogen-based solvent. That is, the composition can be used as an environmentally friendly, halogen-free composition for surface modification. From such a viewpoint, preferred examples of the composition for surface modification may include those that substantially do not contain halogen atoms, and more preferably those that do not contain halogen atoms. In particular, when the composition for surface modification substantially does not contain fluorine atoms such as fluorides, it is also expected that unintended damage to a semiconductor substrate can be effectively suppressed.

As used herein, the phrase “substantially do not contain” means that the case where the component is unavoidably incorporated as an impurity is not excluded. For example, the content of the component in the composition for surface modification is preferably 1 mass % or less, more preferably 0.5 mass % or less, even more preferably 0.3 mass % or less, still even more preferably 0.1 mass % or less, and further preferably 0 mass %.

The composition for surface modification is expected to provide sufficient effects even without containing an organic solvent; however, it is also expected to provide sufficient effects when containing an organic solvent. That is, the composition for surface modification may contain an organic solvent. From such a viewpoint, the content of the organic solvent in the composition for surface modification can be set to from 0 to 95 mass %. The lower limit of the content of the organic solvent may be 0 mass %, and may also be, for example, 5 mass % or more, 10 mass % or more, 20 mass % or more, 30 mass % or more, 40 mass % or more, 50 mass % or more, or 60 mass % or more, depending on components of the composition for surface modification. The upper limit of the content of the organic solvent may be, for example, 90 mass % or less, 80 mass % or less, or 70 mass % or less.

When the composition for surface modification contains water and an organic solvent, the content of the organic solvent relative to the total content of the water and the organic solvent is preferably from 0.05 to 50 mass %. The lower limit of the content ratio may be, for example, 0.1 mass % or more. The upper limit of the content ratio may be 30 mass % or less, 20 mass % or less, or 10 mass % or less. When water and an organic solvent are contained, by setting the content ratio to the above ratio, the solvent can be a water-soluble mixed solvent; therefore, higher water solubility can be imparted to a cleaning solution, and it is expected that solubility of components, reduction of environmental burden, and economic efficiency can be further improved.

### (Impurities and the Like in Composition for Surface Modification)

The composition for surface modification used in the present embodiment may contain metal impurities including at least one metal atom selected from the group consisting of Fe atoms, Cr atoms, Ni atoms, Zn atoms, Ca atoms, and Pb atoms.

The total content of metal atoms in the composition for surface modification used in the present embodiment is preferably 100 mass ppt or less relative to the total mass of the composition for surface modification. The lower limit value of the total content of the metal atoms is preferably as low as possible, and is, for example, 0.001 mass ppt or more. The total content of the metal atoms is, for example, from 0.001 to 100 mass ppt. By setting the total content of metal atoms to be equal to or less than the above-described preferred upper limit value, it is considered that defect suppression and residue suppression of the composition for surface modification can be improved. By setting the total content of metal atoms to be equal to or greater than the above-described preferred lower limit value, the metal atoms are less likely to exist freely in the system, and it is considered that adverse effects on the overall manufacturing yield of an object to be processed can be reduced.

The content of metal impurities can be adjusted, for example, by purification processing such as filtering. The purification processing such as filtering may be performed on a part or all of the raw materials before preparing the composition for surface modification, or may be performed after preparation of the composition for surface modification.

The composition for surface modification used in the present embodiment may contain, for example, impurities derived from organic substances (organic impurities). The total content of the organic impurities in the composition for surface modification used in the present embodiment is preferably 5,000 mass ppm or less. The lower limit value of the content of the organic impurities is preferably as low as possible, and may be, for example, 0.1 mass ppm or more. The total content of the organic impurities may be, for example, from 0.1 to 5,000 mass ppm.

The composition for surface modification used in the present embodiment may contain, for example, an object to be counted having a size that can be counted by a light scattering liquid-borne particle counter. The size of the object to be counted is, for example, 0.04 μm or more. In the composition for surface modification used in the present embodiment, the number of objects to be counted is, for example, 1,000 or less per 1 mL of the composition for surface modification, and the lower limit value thereof is, for example, 0.1 or more. When the number of objects to be counted in the composition for surface modification is within the above-described range, it is considered that metal corrosion suppression effects and defect suppression effects achieved by the composition for surface modification can be improved (however, the mechanism and effects of the present embodiment are not limited thereto).

The above organic impurities and/or the objects to be counted may be added to the composition for surface modification, or may be unavoidably incorporated into the composition for surface modification during a preparation step of the composition for surface modification. Examples of cases in which the organic impurities are unavoidably incorporated during the preparation step of the composition for surface modification may include, but are not limited to, cases where the organic impurities are contained in raw materials used for preparing the composition for surface modification (for example, an organic solvent), and cases where the organic impurities are incorporated from an external environment during the preparation step of the composition for surface modification (for example, contamination).

When the objects to be counted are added to the composition for surface modification, a relative abundance for each specific size may be adjusted in consideration of surface roughness and the like of an object to be processed.

The pH of the composition for surface modification is preferably from 6.0 to 12.0. The lower limit of the pH is more preferably 7.0 or more, and even more preferably 7.5 or more. The upper limit of the pH is more preferably 11.5 or less, and even more preferably 11.0 or less. By controlling the pH of the composition for surface modification to be within the above-described range, repair of damage to a Low-k film and promotion of formation of a barrier layer, which is a subsequent step, can be further improved.

### (Other Subsequent Steps)

The method for manufacturing a semiconductor substrate according to the present embodiment may further include, as needed, performing any optional step after the above-described treatment step. The method for manufacturing a semiconductor substrate according to the present embodiment may further include, after the step of treating (surface treatment) the dry-etched substrate with the composition for surface modification (dry etching step), a step of forming a barrier layer on the substrate subjected to the treatment (surface treatment). For example, a step of forming a barrier layer may be further performed after the treatment step. Examples of the barrier layer described herein may include a film intended to suppress diffusion of wiring metal ions and to enhance adhesion to a wiring substrate. The barrier layer can be formed on a Low-k film after the treatment step by performing film formation using a CVD method with or without plasma enhancement, an ALD method, or a PVD method.

The barrier layer is preferably a layer containing at least one selected from the group consisting of tantalum atoms, titanium atoms, tungsten atoms, cobalt, and silicon. More preferably, the material of the barrier layer is at least one selected from the group consisting of TaN, Ta, TiN, Ti, Co, TaSiN, W₂N, and Si₃N₄. According to the present embodiment, such a barrier layer can exhibit further improved film-forming properties.

### <Method for Etching Substrate>

A method for etching a substrate according to the present embodiment includes a step of dry-etching a substrate including a layer containing a Low-k material (etching step); and a step of treating the dry-etched substrate with a composition for surface modification (treatment step), in which the composition for surface modification contains (A) a silane coupling agent represented by General Formula (1) and/or a derivative thereof; and (B) water. For the etching step and the treatment step, the techniques, conditions, and the like described above in the method for manufacturing a semiconductor substrate can be appropriately employed. As for a composition and properties of the composition for surface modification, the matters described above in the method for manufacturing a semiconductor substrate can also be appropriately employed.

According to the method for etching a substrate of the present embodiment, while etching a substrate including a layer containing a Low-k material, damage to a Low-k film can be repaired, and formation of a barrier layer in a subsequent step can be promoted.

### EXAMPLES

The present invention is described in more detail with reference to the following Examples and Comparative Examples, but the present invention is not limited to the following

### Examples at all.

### <Components>

The abbreviations used in the present Examples are as follows.
BDMADMS:
Bis(dimethylamino)dimethylsilane

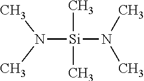

HMDS:
1,1,1,3,3,3-Hexamethyldisilazane

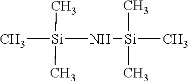

APTES:
3-Aminopropyltriethoxysilane

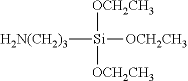

AEAPDMMS:
3-(2-Aminoethylamino) propyldimethoxymethylsilane

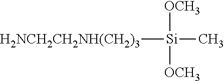

AEAEAPTMS:
3-[2-(2-Aminoethylamino)ethylamino]propyltrimethoxysilane

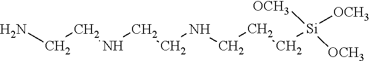 [SMILES: CO[Si](CCCNCCNCCN)(OC)OC]

AcOH:
Acetic acid
3A-TAZ:
3-Amino-1H-1,2,4-triazole

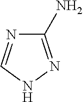

TAZ:
1,2,4-Triazole

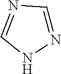

5M-BTA:
5-Methyl-1H-benzotriazole

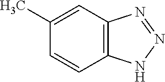

PGMEA:
Propylene glycol methyl ether acetate
DIW:
Water
EDG:
Diethylene glycol monoethyl ether
1,3-Propanediol:
1,3-Propanediol

### <Preparation of Composition for Surface Modification>

A composition for surface modification was prepared so as to have the composition shown in each table. For example, the composition for surface modification of Example 1 is a composition containing 0.1 mass % of APTES, 0.017 mass % of AcOH, 0.1 mass % of 3A-TAZ, and water (DIW) as a balance, and having a pH of 9.5.

### <Evaluation of TaN ALD Deposition Amount>

### (Deposition Amount of Reference Example)

A laminated substrate including a Low-k layer on a substrate (a 12-inch silicon substrate) was prepared. The laminated substrate was subjected to dry etching under conditions including CF-based gas (etching step). Subsequently, a TaN film was formed on the substrate (a 12-inch silicon substrate) by an atomic layer deposition (ALD) method under plasma-enhanced conditions using pentakis (dimethylamino) tantalum (PDMAT) and NH₃, after the substrate was heated at 350° C. for 2 minutes. The thickness of the TaN film was measured by XRF. This was used as a Reference Example. That is, the Reference Example corresponds to a case in which only the dry etching step is performed and a treatment step described below is not performed.

### (Deposition Amount of Examples and Comparative Examples)

A laminated substrate including a Low-k layer on a substrate (a 12-inch silicon substrate) was prepared. The laminated substrate was subjected to dry etching under conditions including CF-based gas (etching step). Subsequently, the laminated substrate subjected to the dry etching was treated using the composition for surface modification of each Example and each Comparative Example (treatment step). Specifically, after immersing the laminated substrate for 2 minutes in a beaker containing the composition for surface modification maintained at 25° C., the processing solution was completely replaced with DIW or IPA, and after drying using an N₂ blow, the substrate was heated at 350° C. for 2 minutes. Subsequently, a TaN film was formed on the substrate (the 12-inch silicon substrate) by an atomic layer deposition (ALD method) under plasma-enhanced conditions, using pentakis (dimethylamino) tantalum (PDMAT) and NH₃. The thickness of the TaN film was measured by XRF.

The deposition amount (TaN ALD deposition amount) of each of the Examples and Comparative Examples was evaluated by defining the thickness of the TaN film in the Reference Example as 100%, calculating a relative ratio with respect thereto, and applying the following criteria.
A: The TaN ALD deposition amount was 100% or more.
B: The TaN ALD deposition amount was 80% or more and less than 100%.
C: The TaN ALD deposition amount was less than 80%.

### <Evaluation of Dielectric Constant Improvement Ratio>

### (Dielectric Constant of Reference Example)

A laminated substrate including a Low-k layer on a substrate (a 12-inch silicon substrate) was prepared. The laminated substrate was subjected to dry etching under conditions including CF-based gas (etching step). Subsequently, using a substrate heated at 350° C. for 2 minutes, the dielectric constant was measured by C-V measurement using a mercury probe method. This was used as a Reference Example.

### (Dielectric Constant Improvement Ratio of Examples and Comparative Examples)

A laminated substrate including a Low-k layer on a substrate (a 12-inch silicon substrate) was prepared. The laminated substrate was subjected to dry etching under conditions including CF-based gas (etching step). Subsequently, the laminated substrate subjected to the dry etching was treated using the composition for surface modification of each Example and each Comparative Example (treatment step). Specifically, after immersing the laminated substrate for 2 minutes in a beaker containing the composition for surface modification maintained at 25° C., the processing solution was completely replaced with DIW or IPA, and after drying using an N₂ blow, the substrate was heated at 350° C. for 2 minutes. The prepared substrates were measured by C-V measurement using a mercury probe method.

The dielectric constant improvement ratio of each of the Examples and Comparative Examples was evaluated by calculating a relative permittivity using the capacitance measured by the C-V measurement and the thickness of the Low-k film, defining the value of the Reference Example as 100%, calculating a relative ratio (dielectric constant improvement ratio) with respect thereto, and applying the following criteria.
A: The dielectric constant improvement ratio was 3.0% or more.
B: The dielectric constant improvement ratio was 0.0% or more and less than 3.0%.
C: The dielectric constant improvement ratio was less than 0%.

The compositions, properties, and evaluation results of the Reference Example, Examples 1 to 5, and Comparative Examples 1 and 2 are shown in Table 1. The compositions, properties, and evaluation results of Examples 6 to 12 are shown in Table 2. The compositions, properties, and evaluation results of Examples 13 to 18 are shown in Table 3.

TABLE 1

| | | Reference | Comparative | Comparative |
|---|---|---|---|---|
| | | Example | Example 1 | Example 2 |
| Composition | Silane coupling agent | None | BDMADMS | HMDS |
| | Content | | 1 wt % | 1 wt % |
| | pH adjusting agent | None | None | None |
| | Content | | | |
| | Corrosion inhibitor | None | None | None |
| | Content | | | |
| | Organic solvent | None | PGMEA | PGMEA |
| | Content | | 99 wt % | 99 wt % |
| | Water (DIW) | None | None | None |
| | Content | | | |

| | | | |
|---|---|---|---|
| pH | — | — | — |
| TaN ALD deposition amount | 100% | 33.3% | 47.9% |
| TaN deposition evaluation | — | C | C |
| Dielectric constant | 0% | 0.80% | 1.20% |
| improvement ratio | | | |
| Dielectric constant evaluation | — | B | B |

| | | Example 1 | | Example 2 | | Example 3 | | Example 4 | | Example 5 | |
|---|---|---|---|---|---|---|---|---|---|---|---|
| Composition | Silane coupling agent | APTES | | APTES | | APTES | | APTES | | APTES | |
| | Content | 0.1 | wt % | 0.25 | wt % | 0.95 | wt % | 0.95 | wt % | 0.95 | wt % |
| | pH adjusting agent | AcOH | | AcOH | | AcOH | | AcOH | | AcOH | |
| | Content | 0.017 | wt % | 0.044 | wt % | 0.157 | wt % | 0.20 | wt % | 0.20 | wt % |
| | Corrosion inhibitor | 3A-TAZ | | 3A-TAZ | | 3A-TAZ | | 3A-TAZ | | 3A-TAZ | |
| | Content | 0.1 | wt % | 0.1 | wt % | 0.1 | wt % | 0.1 | wt % | 0.1 | wt % |

| Organic solvent | None | None | None | EDG | | 1,3- | |
|---|---|---|---|---|---|---|---|
| | | | | | | Propanediol | |
| Content | | | | 10 | wt % | 50 | wt % |

| | | | | | |
|---|---|---|---|---|---|
| Water (DIW) | DIW | DIW | DIW | DIW | DIW |
| Content | Balance | Balance | Balance | Balance | Balance |

| | | | | | |
|---|---|---|---|---|---|
| pH | 9.5 | 9.5 | 9.5 | 9 | 8.7 |
| TaN ALD deposition amount | 89.6% | 93.8% | 100.0% | 89.6% | 89.6% |
| TaN deposition evaluation | B | B | A | B | B |
| Dielectric constant | 3.70% | 4.00% | 5.00% | 0.83% | 2.03% |
| improvement ratio | | | | | |
| Dielectric constant evaluation | A | A | A | B | B |

TABLE 2

| | | Example 6 | Example 7 | Example 8 | Example 9 | Example 10 |
|---|---|---|---|---|---|---|
| Composition | Silane | APTES | | | | |
| | coupling | | | | | |
| | agent | | | | | |
| | Content | 1 wt % | | | | |
| | pH adjusting | None | AcOH | | | |
| | agent | | | | | |
| | Content | | 0.26 wt % | | | |
| | Corrosion | None | None | TAZ | 3A-TAZ | 5M-BTA |
| | inhibitor | | | | | |
| | Content | | | 0.1 wt % | 0.1 wt % | 0.1 wt % |
| | Organic | None | None | None | None | None |
| | solvent | | | | | |
| | Content | | | | | |
| | Water (DIW) | DIW | DIW | DIW | DIW | DIW |
| | Content | Balance | Balance | Balance | Balance | Balance |

| | | | | | |
|---|---|---|---|---|---|
| pH | 10.6 | 8.5 | 8.5 | 8.6 | 8.5 |
| TaN ALD deposition amount | 85.4% | 106.3% | 100.6% | 97.9% | 102.1% |
| TaN deposition evaluation | B | A | A | B | A |
| Dielectric constant | 4.80% | 5.00% | 5.00% | 5.74% | 5.30% |
| improvement ratio | | | | | |
| Dielectric constant evaluation | A | A | A | A | A |

| | | Example 11 | Example 12 |
|---|---|---|---|
| Composition | Silane | AEAPDMMS | AEAEAPTMS |
| | coupling | | |
| | agent | | |
| | Content | 1 wt % | 1 wt % |
| | pH adjusting | None | None |
| | agent | | |
| | Content | | |
| | Corrosion | None | None |
| | inhibitor | | |
| | Content | | |
| | Organic | None | None |
| | solvent | | |
| | Content | | |
| | Water (DIW) | DIW | DIW |
| | Content | Balance | Balance |

| | | |
|---|---|---|
| pH | 10.7 | 10.4 |
| TaN ALD deposition amount | 95.8% | 91.7% |
| TaN deposition evaluation | B | B |
| Dielectric constant | 4.20% | 3.20% |
| improvement ratio | | |
| Dielectric constant evaluation | A | A |

TABLE 3

| | | Example 13 | Example 14 | Example 15 | Example 16 | | Example 17 | | Example 18 | |
|---|---|---|---|---|---|---|---|---|---|---|
| Composition | Silane | APTES | AEAPDMMS | AEAEAPTMS | AEAEAPTMS | | AEAEAPTMS | | AEAEAPTMS | |
| | coupling | | | | | | | | | |
| | agent | | | | | | | | | |
| | Content | 1 wt % | 1 wt % | 1 wt % | 0.1 | wt % | 0.25 | wt % | 0.95 | wt % |
| | pH | None | None | None | AcOH | | AcOH | | AcOH | |
| | adjusting | | | | | | | | | |
| | agent | | | | | | | | | |
| | Content | | | | 0.017 | wt % | 0.049 | wt % | 0.190 | wt % |
| | Corrosion | None | None | None | 3A-TAZ | | 3A-TAZ | | 3A-TAZ | |
| | inhibitor | | | | | | | | | |
| | Content | | | | 0.1 | wt % | 0.1 | wt % | 0.1 | wt % |

| | | | | | | |
|---|---|---|---|---|---|---|
| Organic | None | None | None | None | None | None |
| solvent | | | | | | |
| Content | | | | | | |
| Water | DIW | DIW | DIW | DIW | DIW | DIW |
| (DIW) | | | | | | |
| Content | Balance | Balance | Balance | Balance | Balance | Balance |

| pH | 10.6 | 10.7 | 10.4 | 9.5 | 9.5 | 9.5 |
|---|---|---|---|---|---|---|
| TaN ALD deposition | 85.4% | 85.4% | 83.3% | 88.1% | 83.3% | 95.8% |
| amount | | | | | | |
| TaN deposition evaluation | B | B | B | B | B | B |
| Dielectric constant | 4.80% | 4.20% | 3.20% | 2.90% | 4.90% | 6.20% |
| improvement ratio | | | | | | |
| Dielectric constant | A | A | A | B | A | A |
| evaluation | | | | | | |

From the above, it was confirmed at least that, according to the present Examples, it is possible to repair damage to the Low-k film while promoting formation of a barrier layer in a subsequent step.

What is claimed is:

1. A method for manufacturing a semiconductor substrate, the method comprising:
a step of dry-etching a substrate comprising a layer comprising a Low-k material; and
a step of treating the dry-etched substrate with a composition for surface modification,
wherein the composition for surface modification comprises: (A) a silane coupling agent represented by General Formula (1) and/or a derivative thereof; and (B) water, 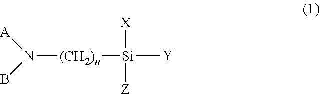
wherein, in General Formula (1), A and B each independently represent a hydrogen atom, a hydroxy group, a hydrocarbon group, or an organic group containing a nitrogen atom, and at least one of A and B represents a hydrogen atom; X and Y each independently represent an alkyl group, an alkoxy group, a hydrogen atom, a halogen atom, or a hydroxy group; Z represents an alkoxy group or a hydroxy group; and n represents a number.

2. The method for manufacturing a semiconductor substrate according to claim 1, wherein the composition for surface modification further comprises (C) a corrosion inhibitor.

3. The method for manufacturing a semiconductor substrate according to claim 2, wherein the corrosion inhibitor (C) is a compound comprising an aromatic ring structure containing a nitrogen atom.

4. The method for manufacturing a semiconductor substrate according to claim 1, wherein a content of the component (A) in the composition for surface modification is from 0.01 to 10 mass %.

5. The method for manufacturing a semiconductor substrate according to claim 2, wherein a content of the component (C) in the composition for surface modification is from 0.001 to 5 mass %.

6. The method for manufacturing a semiconductor substrate according to claim 1, wherein the composition for surface modification has a pH of 6.0 to 12.0.

7. A method for etching a substrate, the method comprising:
a step of dry-etching a substrate comprising a layer comprising a Low-k material; and
a step of treating the dry-etched substrate with a composition for surface modification,
wherein the composition for surface modification contains: (A) a silane coupling agent represented by General Formula (1) and/or a derivative thereof; and (B) water, 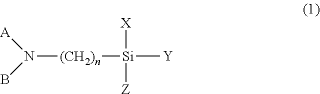
wherein, in General Formula (1), A and B each independently represent a hydrogen atom, a hydroxy group, a hydrocarbon group, or an organic group containing a nitrogen atom, and at least one of A and B represents a hydrogen atom; X and Y each independently represent an alkyl group, an alkoxy group, a hydrogen atom, a halogen atom, or a hydroxy group; Z represents an alkoxy group or a hydroxy group; and n represents a number.

8. The method for etching a substrate according to claim 7, wherein the composition for surface modification further comprises (C) a corrosion inhibitor.

9. The method for etching a substrate according to claim 7, wherein the composition for surface modification has a pH of 6.0 to 12.0.

10. A composition for surface modification of a substrate comprising a layer comprising a Low-k material, the composition comprising:
(A) a silane coupling agent represented by General Formula (1) and/or a derivative thereof; and (B) water, 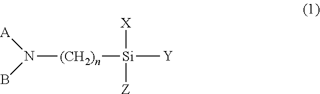
wherein, in General Formula (1), A and B each independently represent a hydrogen atom, a hydroxy group, a hydrocarbon group, or an organic group containing a nitrogen atom, and at least one of A and B represents a hydrogen atom; X and Y each independently represent an alkyl group, an alkoxy group, a hydrogen atom, a halogen atom, or a hydroxy group; Z represents an alkoxy group or a hydroxy group; and n represents a number.

11. The composition for surface modification according to claim 10, further comprising (C) a corrosion inhibitor.

12. The composition for surface modification according to claim 11, wherein the corrosion inhibitor (C) is a compound comprising an aromatic ring structure containing a nitrogen atom.

13. The composition for surface modification according to claim 10, wherein a content of the component (A) in the composition for surface modification is from 0.01 to 10 mass %.

14. The composition for surface modification according to claim 11, wherein a content of the component (C) in the composition for surface modification is from 0.001 to 5 mass %.

15. The composition for surface modification according to claim 10, wherein the composition for surface modification has a pH of 6.0 to 12.0.
